(19) United States
(12) Patent Application Publication
(10) Pub. No.: US 2012/0280345 A1
(43) Pub. Date: Nov. 8, 2012

(54) PHOTODETECTOR AND A METHOD OF FORMING THE SAME

(75) Inventors: Shiyang Zhu, Singapore (SG); Guo-Qiang Patrick Lo, Singapore (SG)

(73) Assignee: Agency for Science, Technology and Research

(21) Appl. No.: 13/464,763

(22) Filed: May 4, 2012

(30) Foreign Application Priority Data
May 5, 2011 (SG) 201103211-7

(51) Int. Cl. H01L 31/0232; H01L 31/18

(52) U.S. Cl. 257/432; 438/59; 257/E31.127

(57) ABSTRACT

According to embodiments of the present invention, a photodetector is provided. The photodetector includes a substrate, a waveguide formed on a surface of the substrate, a first metal layer formed on a first side of the waveguide, wherein a first interface is defined between the waveguide and the first metal layer, and a silicide layer formed on a second side of the waveguide, wherein a second interface is defined between the waveguide and the silicide layer, and wherein the second side is opposite to the first side, and wherein at least one of the first interface and the second interface is at least substantially perpendicular to the surface of the substrate. Various embodiments further provide a method of forming the photodetector.

### CROSS-REFERENCE TO RELATED APPLICATIONS

This application claims the benefit of priority of Singapore patent application No. 201103211-7, filed 5 May 2011, the content of which is hereby incorporated by reference in its entirety for all purposes.

### TECHNICAL FIELD

Various embodiments relate to a photodetector and a method of forming the photodetector.

### BACKGROUND

The continuous increase in speed and bandwidth of modern electronic circuits requires integration of optical devices to overcome the interconnection bottleneck. However, the conventional silicon (Si) electronic photonic integrated circuits (EPICs) face a critical challenge of the dimension mismatch between the micrometer scales of diffraction-limited optical devices and nanometer scales of electronic devices.

Plasmonics, which deals with surface plasmon polariton (SPP) excitation and propagation at metal-dielectric interfaces, can confine light far beyond the diffraction limit, thus showing a great potential to bridge the dimension mismatch between the electronics and photonics. A number of ultra-compact plasmonic devices have been proposed or demonstrated to generate, guide, modulate, and detect the SPP signals. A plasmon detector is one of the blocks of integrated plasmonic circuits. Up to date, the fabrication of most plasmonic devices requires a non-standard CMOS technology, e.g., (1) Au or Ag,—which are not CMOS-compatible material, is commonly used as the metal; (2) a special process, such as electron beam lithography, is usually required to fabricate the nanostructure; and (3) a unique active material, such as CdSe quantum dot (QD), Ge, or GaAs, etc, is required for the active plasmonic devices.

However, in the view of practical implementation of plasmonic devices in the existing Si EPICs, it is highly desirable to use fully CMOS compatible materials (e.g. Al, Cu, or silicide, etc.) and industry-standard lithographic process. Recently, horizontal Al/SiO₂/Si/SiO₂/Al and Cu/SiO₂/Si/SiO₂/Cu nanoplasmonic slot waveguides were demonstrated using the standard CMOS technology to exhibit high coupling efficiency to the conventional Si dielectric waveguide and very low bending loss. The Cu-waveguide has lower propagation loss than the Al-counterpart, indicating that it is a promising plasmonic waveguide for various plasmonic devices. A nanoplasmonic modulator based on the above horizontal plasmonic waveguide was proposed. It is therefore necessary to develop a detector to convert the SPP signal propagating along the plasmonic waveguide directly to the electrical signal to provide a complete plasmo-electronic nanocircuit.

In Si photonics, germanium is commonly used to detect the 0.8-eV photons (i.e. at the communication wavelength of 1550 nm). Because Ge has a relatively small absorption coefficient of ˜0.046 μm⁻¹ at 1550 nm, a thick or long Ge active layer is required for the sufficient light absorption. To shrink the detector into nanometer scale,—which is required for nanoplasmonic detectors, a precise cavity or antenna structure should be developed to confine the light into a very small volume. However, although high-quality Ge film can be grown on Si, the heteroepitaxy of Ge on Si is an expensive and tough process. It also makes the whole fabrication flow of integrated circuits complex and/or difficult, especially accompanied with the fabrication of a pretty nanocavity or antenna structure.

Silicide Schottky barrier detector (SBD) is an attractive alternative for infrared detection, in which light is absorbed by silicide and the photoexcited carriers in the silicide layer can emit over the Schottky barrier (Φ_{B}) to be collected as photocurrent. It can detect photons of energy (hv) between Φ_{B} and the Si bandgap (1.12 eV). Because silicide typically has a very large absorption coefficient, e.g. ˜20.66 μm⁻¹ for TaSi₂ at 1550 nm, the silicide SBD requires a much thinner or shorter silicide layer for light absorption than the Ge-counterpart. More importantly, the silicide SBD can be easily fabricated using the standard CMOS technology. However, the silicide SBD suffers a major shortcoming of low responsivity mainly due to its low internal quantum efficiency. Reducing the barrier height Φ_{B} and thinning down the silicide thickness to much less than the hot carrier attenuation length can improve the internal quantum efficiency. However, the former leads to a large dark current unless the detector is operated at cryogenic temperature and the latter reduces the light absorption. Regarding the first problem, a suitable Φ_{B} should be selected to compromise the responsivity and the dark current. However, as Φ_{B} is mainly determined by the silicide itself, it can be tuned over very limited range by an applied voltage. To alleviate the second problem, one can use an optical cavity and/or put the silicide layer on the Si waveguide. A 2-nm-thick PtSi/p-Si Schottky detector (Φ_{B}˜0.21 eV) having an optical cavity was demonstrated with a responsivity up to ˜0.25 A/W at 1.5 μm, but it operated at 40 K. A Si waveguide-based NiSi₂/p-Si Schottky detector (Φ_{B}˜0.53 eV) can operate at room temperature with the dark current of ˜3 nA, but its responsivity is only ˜4.6 mA/W. To meet the requirement for Si-EPIC application, the responsivity of silicide SBD needs to be substantially improved while keeping the dark current low enough to operate at room temperature.

### SUMMARY

According to an embodiment, a photodetector is provided. The photodetector may include a substrate, a waveguide formed on a surface of the substrate, a first metal layer formed on a first side of the waveguide, wherein a first interface is defined between the waveguide and the first metal layer, and a silicide layer formed on a second side of the waveguide, wherein a second interface is defined between the waveguide and the silicide layer, and wherein the second side is opposite to the first side, and wherein at least one of the first interface or the second interface is at least substantially perpendicular to the surface of the substrate.

According to an embodiment, a method of forming a photodetector is provided. The method may include providing a substrate, forming a waveguide on a surface of the substrate, forming a first metal layer on a first side of the waveguide, wherein a first interface is defined between the waveguide and the first metal layer, and forming a silicide layer on a second side of the waveguide, wherein a second interface is defined between the waveguide and the silicide layer, and wherein the second side is opposite to the first side, and wherein at least one of the first interface or the second interface is at least substantially perpendicular to the surface of the substrate.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a schematic block diagram of a photodetector, while FIG. 1B shows a simplified cross-sectional representation of the photodetector of the embodiment of FIG. 1A, according to various embodiments.

FIG. 2 shows a flow chart illustrating a method of forming a photodetector, according to various embodiments.

FIG. 3A shows a schematic perspective view of a photodetector, according to various embodiments.

FIG. 3B shows a schematic cross-sectional view of the photodetector of the embodiment of FIG. 3A along the line A1-A1′.

FIG. 3C shows a schematic cross-sectional view of the photodetector of the embodiment of FIG. 3A along the line A2-A2′.

FIG. 3D shows a schematic cross-sectional view of the photodetector of the embodiment of FIG. 3A along the line A3-A3′.

FIGS. 4A to 4M show the top or cross-sectional views of a fabrication process to manufacture a photodetector, according to various embodiments.

FIG. 4N shows a cross sectional transmission electron microscopy (XTEM) image of a front view of a photodetector, according to various embodiments.

FIG. 4O shows a cross sectional transmission electron microscopy (XTEM) image of a front view of a nanoplasmonic waveguide of the embodiment of FIG. 4N.

FIG. 4P shows a cross sectional transmission electron microscopy (XTEM) image of a front view of a nanoplasmonic waveguide of a photodetector, according to various embodiments.

FIG. 5 shows a map of calculated propagation loss as a function of the real and imaginary index of the silicide.

FIGS. 6A and 6B show respectively the y-component magnetic field (H_{y}) distributions along the waveguide (z-direction) and the x-component electric field (Eₓ) along a cross section of the waveguide for a silicide having a complex index of 1.0+1.5i.

FIGS. 6C and 6D show respectively the y-component magnetic field (H_{y}) distributions along the waveguide (z-direction) and the x-component electric field (Eₓ) along a cross section of the waveguide for a silicide having a complex index of 4.0+5.0i.

FIG. 7A shows a schematic of a band diagram of a silicide/Si/silicide structure under a positive bias, according to various embodiments.

FIG. 7B shows a plot 720 of internal quantum efficiency (ηᵢ) of a thin-film silicide/Si Schottky-barrier photodetector of various embodiments, for different Schottky barrier heights (Φ_{B}).

FIGS. 8A and 8B show respective plots of calculated absorption (A) and external quantum efficiency (ηₑ) as a function of TaSi₂ thickness (W_{TaSi2}), according to various embodiments.

FIG. 9 shows a plot of calculated propagation loss (a) and absorption (A) as a function of silicon (Si) core width (W_{Si}), according to various embodiments.

FIG. 10 shows a plot of calculated propagation loss (α) and absorption (A) as a function of silicon nitride (Si₃N₄) isolator width (W_{SiN}), according to various embodiments.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the methods or devices are analogously valid for the other method or device. Similarly, embodiments described in the context of a method are analogously valid for a device, and vice versa.

In the context of various embodiments, the phrase “at least substantially” may include “exactly” and a variance of +/−5% thereof. As an example and not limitations, “A is at least substantially same as B” may encompass embodiments where A is exactly the same as B, or where A may be within a variance of +/−5%, for example of a value, of B, or vice versa.

In the context of various embodiments, the term “about” or “approximately” as applied to a numeric value encompasses the exact value and a variance of +/−5% of the value.

As used herein, the term “and/or” includes any and all combinations of one or more of the associated listed items.

Various embodiments may be related to a plasmonic detector or photodetector for integration in electronic photonic plasmonic integrated circuits, for example to directly convert surface plasmon polariton (SPP) signal to electric signal. A circuit or device incorporating the photodetector of various embodiments may be provided. The circuit with the detector may be used in applications for communication, bio-sensor, etc.

Various embodiments may provide a Schottky barrier nanoplasmonic detector or photodetector and a method for forming the same. Various embodiments may provide a silicide Schottky barrier detector (e.g. photodetector) integrated in a horizontal nanoplasmonic slot waveguide. Various embodiments may provide an integrated plasmonic detector or photodetector, which is fully CMOS compatible and offers a very high speed.

Various embodiments may provide an integrated silicide Schottky barrier detector designed to electrically detect surface plasmons propagating along a horizontal metal/insulator/Si/insulator/metal nanoplasmonic waveguide (e.g. slot waveguide), for example at the telecommunication wavelength of 1.55 μm. In various embodiments, ultrathin silicide layers may be inserted between the Si core and the insulators to absorb the optical power effectively, and the silicide/Si Schottky barrier height of the silicide/Si/silicide structure with a very narrow Si core may be substantially tuned by an applied voltage through the Schottky effect. The mechanism of a silicide Schottky barrier detector is based on (Φ_{B}<hv<E_{g}), where Φ_{B} refers to the Schottky barrier height, hv refers to the photon energy and E_{g} refers to the bandgap (e.g. Si bandgap).

Various embodiments may provide a plasmonic photodetector (e.g. a silicide SPP structure) directly integrated in a horizontal plasmonic waveguide to detect surface plasmon polariton (SPP) signal propagating along a plasmonic waveguide (e.g. having a Si waveguide or core) of the photodetector. The photodetector may have a horizontal silicide/Si/silicide metal-semiconductor-metal (MSM) structure integrated in a horizontal metal/insulator/Si/insulator/metal plasmonic or nanoplasmonic waveguide. The light confinement within the photodetector provides an effective absorption. In various embodiments, the Schottky barrier of the photodetector may be tunable, due to the metal-semiconductor-metal (MSM) structure with a very narrow semiconductor (e.g. Si) core width, by an applied voltage. The photodetector may have a high speed due to the ultracompact structure. Various embodiments may further provide an easy and fully Si-CMOS compatible fabrication process, as compared to other SPP detectors (e.g. Ge or GaAs based).

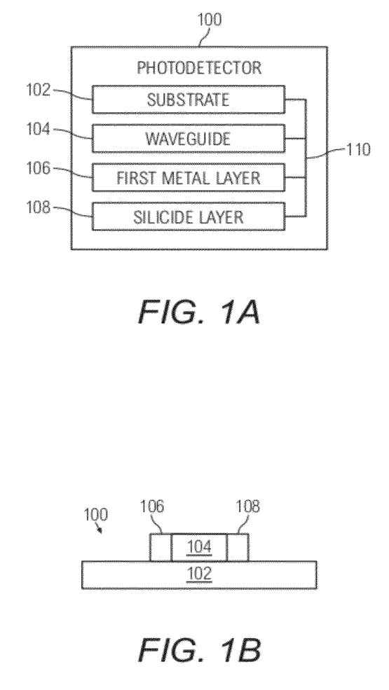

FIG. 1A shows a schematic block diagram of a photodetector 100, while FIG. 1B shows a simplified cross-sectional representation of the photodetector 100 of the embodiment of FIG. 1A, according to various embodiments.

The photodetector 100 includes a substrate 102, a waveguide (e.g. a Si waveguide or core) 104 formed on a surface of the substrate 102, a first metal layer 106 formed on a first side of the waveguide 104, wherein a first interface is defined between the waveguide 104 and the first metal layer 106, and a silicide layer 108 formed on a second side of the waveguide 104, wherein a second interface is defined between the waveguide 104 and the silicide layer 108, and wherein the second side is opposite to the first side, and wherein at least one of the first interface or the second interface is at least substantially perpendicular to the surface of the substrate 102. In FIG. 1A, the line represented as 110 is illustrated to show the relationship between the different components, which may include electrical coupling and/or mechanical coupling and/or optical coupling. In FIG. 1B, it should be appreciated that the positions of the first metal layer 106 and the silicide layer 108 may be interchangeable.

In various embodiments, the first interface may be at least substantially perpendicular to the surface of the substrate 102, or the second interface may be at least substantially perpendicular to the surface of the substrate 102, or both the first interface and the second interface may be at least substantially perpendicular to the surface of the substrate 102.

In various embodiments, the photodetector 100 may further include a second metal layer formed adjacent to the first metal layer 106, and a third metal layer formed adjacent to the silicide layer 108. The second metal layer and the third metal layer may be formed on the surface of the substrate 102.

In various embodiments, the photodetector 100 may further include a first dielectric layer formed between the first metal layer 106 and the second metal layer, and a second dielectric layer formed between the silicide layer 108 and the third metal layer. The first dielectric layer may be formed partially in a longitudinal direction of the waveguide 104, and wherein the second dielectric layer may be formed partially in the longitudinal direction of the waveguide 104.

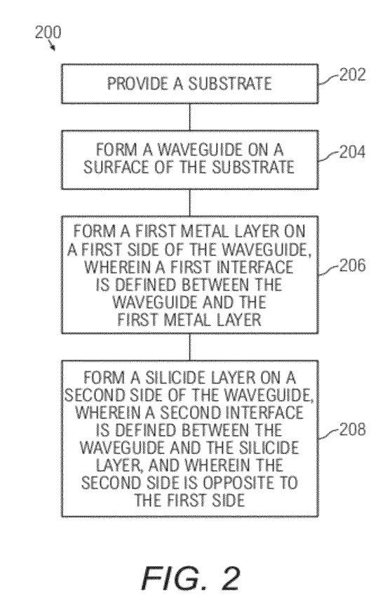

FIG. 2 shows a flow chart 200 illustrating a method of forming a photodetector, according to various embodiments.

At 202, a substrate is provided.

At 204, a waveguide is formed on a surface of the substrate.

At 206, a first metal layer is formed on a first side of the waveguide, wherein a first interface is defined between the waveguide and the first metal layer.

At 208, a silicide layer is formed on a second side of the waveguide, wherein a second interface is defined between the waveguide and the silicide layer, and wherein the second side is opposite to the first side.

In various embodiments, the photodetector is formed such that at least one of the first interface or the second interface is at least substantially perpendicular to the surface of the substrate. In various embodiments, the first interface may be at least substantially perpendicular to the surface of the substrate, or the second interface may be at least substantially perpendicular to the surface of the substrate, or both the first interface and the second interface may be at least substantially perpendicular to the surface of the substrate.

In various embodiments, the method may further include forming a second metal layer adjacent to the first metal layer, and forming a third metal layer adjacent to the silicide layer. In various embodiments, forming the second metal layer may include forming the second metal layer on the surface of the substrate and forming the third metal layer may include forming the third metal layer on the surface of the substrate.

In various embodiments, the method may further include forming a first dielectric layer between the first metal layer and the second metal layer, and forming a second dielectric layer between the silicide layer and the third metal layer. In various embodiments, forming the first dielectric layer may include forming the first dielectric layer partially in a longitudinal direction of the waveguide, and forming the second dielectric layer may include forming the second dielectric layer partially in the longitudinal direction of the waveguide.

In the context of various embodiments, the first metal layer (e.g. 106) may be another silicide layer. In the context of various embodiments, the silicide layer (e.g. 108) and the other silicide layer (e.g. equivalent to 106) may include an at least substantially same material or different materials. Each of the silicide layer (e.g. 108) and the other silicide layer may include a material having a complex refractive index, wherein the complex refractive index has a real index and an imaginary index, and wherein the real index may be between about 1 and about 6 (e.g. between about 1 and about 4, between about 1 and about 2 or between about 3 and about 6) and the imaginary index may be between about 0 and about 5.5 (e.g. between about 0 and about 4, between about 0 and about 2, or between about 3 and about 5.5).

In the context of various embodiments, each of the silicide layer (e.g. 108) and the other silicide layer may include a material selected from a group consisting of cobalt silicide (CoSi), nickel silicide (NiSi), titanium silicide (TiSi), palladium silicide (PdSi), hafnium silicide (HfSi), niobium silicide (NbSi), platinum silicide (PtSi), vanadium silicide (VSi), tantalum silicide (TaSi) and any combinations thereof.

In the context of various embodiments, a first Schottky barrier (e.g. a first silicide diode) may be formed at the first interface, and a second Schottky barrier (e.g. a second silicide diode) may be formed at the second interface. One of the first Schottky barrier or the second Schottky barrier may be forward biased, and the other Schottky barrier may be reverse biased when a voltage is applied between the first metal layer (e.g. 106) and the silicide layer (e.g. 108).

In the context of various embodiments, each of the second metal layer and the third metal layer may include copper (Cu), aluminium (Al), gold (Au), silver (Ag) or any alloys of these materials.

In the context of various embodiments, the first metal layer (e.g. 106) has a first permittivity, the silicide layer (e.g. 108) has a second permittivity, the first dielectric layer has a third permittivity and the second dielectric layer has a fourth permittivity, wherein the third permittivity and the fourth permittivity may be lower than the first permittivity and the second permittivity. In the context of various embodiments, the first permittivity and the second permittivity may be lower than a permittivity of a material of the waveguide (e.g. 104).

In the context of various embodiments, each of the first dielectric layer and the second dielectric layer may include silicon oxide, silicon nitride, silicon oxynitride, hafnium oxide, hafnium oxynitride or any other high-κ dielectric materials.

In the context of various embodiments, each of the first dielectric layer and the second dielectric layer may have a width of between about 1 nm and about 40 nm, e.g. between about nm and about 20 nm, between about 1 nm and about 10 nm or between about 10 nm and about 40 nm.

In the context of various embodiments, each of the first metal layer (e.g. 106) and the silicide layer (e.g. 108) may have a width of between about 1 nm and about 10 nm, e.g. between about 1 nm and about 5 nm, between about 1 nm and about 3 nm or between about 5 nm and about 10 nm.

In the context of various embodiments, the waveguide (e.g. 104) may include a semiconductor. In various embodiments, the waveguide (e.g. 104) may include silicon.

In the context of various embodiments, each of the first side of the silicon waveguide and the second side of the silicon waveguide may be silicon (110) crystal planes.

In the context of various embodiments, the waveguide (e.g. 104) may include a slot waveguide or a rib waveguide.

In the context of various embodiments, the waveguide (e.g. 104) may have a width of between about 10 nm and about 100 nm, e.g. between about 10 nm and about 80 nm, between about 10 nm and about 50 nm, between about 10 nm and about 30 nm, between about 30 nm and about 100 nm or between about 50 nm and about 100 nm.

In the context of various embodiments, the waveguide (e.g. 104) may have a height of between about 100 nm and about 500 nm, e.g. between about 100 nm and about 300 nm, between about 100 nm and about 200 nm, or between about 300 nm and about 500 nm.

In the context of various embodiments, the photodetector (e.g. 100) may have an absorption length of between about 0.5 μm and about 10 μm, e.g. between about 0.5 μm and about 5 μm, between about 0.5 μm and about 2 μm, between about 2 μm and about 10 μm, or between about 5 μm and about 10 μm.

In the context of various embodiments, the terms “dielectric”, “isolator” and “insulator” may be interchangeably used.

In the context of various embodiments, a MSM structure means a metal-semiconductor-metal structure, which is a term normally used in the silicide photodetector field, while a MDM structure means a metal-dielectric-metal structure, which is a term normally used in the plasmonic waveguide field. In the context of various embodiments, the terms (MSM) and (MDM) may be equivalent and/or may be interchangeably used.

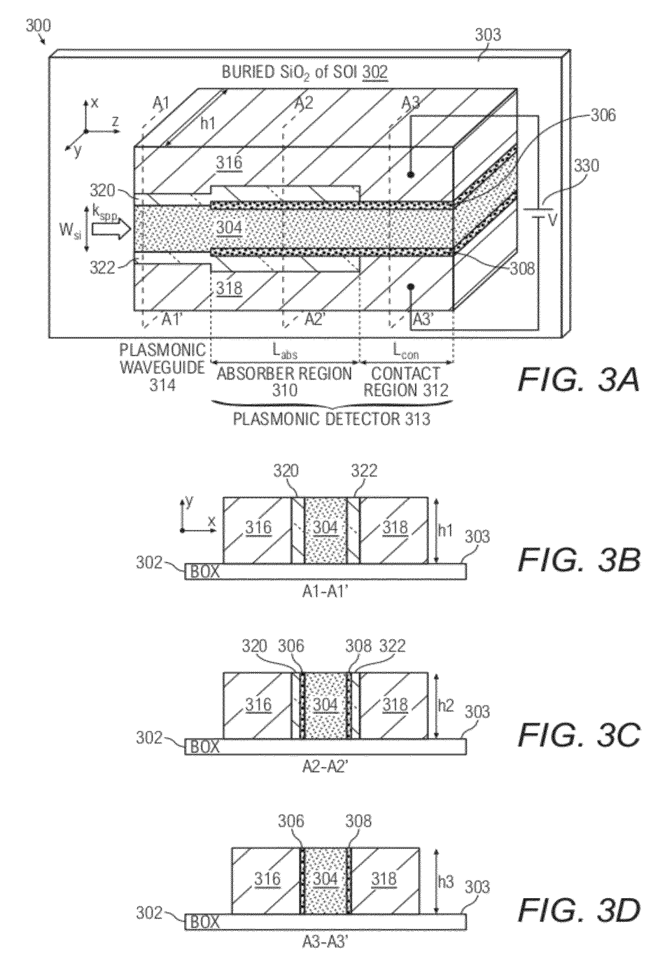

FIG. 3A shows a schematic perspective view of a photodetector 300, according to various embodiments. The photodetector 300 may be a plasmonic waveguide based silicide Schottky barrier detector.

The photodetector 300 includes a substrate 302, for example a silicon-on-insulator (SOI) or a buried oxide (BOX), e.g. SiO₂ of a SOI. The photodetector 300 further includes a waveguide 304, e.g. a slot waveguide or a rib waveguide, formed on or over the substrate, e.g. on the surface 303 of the substrate 302. The waveguide 304 may be part of a plasmonic waveguide. The waveguide 304 may include a semiconductor, e.g. silicon (Si). In various embodiments, the waveguide 304 may include or may be a silicon core. The photodetector 300 further includes a silicide layer 306 formed on one side of the waveguide 304, defining an interface between the waveguide 304 and the silicide layer 306, and a silicide layer 308 formed on another side of the waveguide 304, defining an interface between the waveguide 304 and the silicide layer 308. The silicide layers 306, 308 are formed on opposite sides of the waveguide 304. The respective interfaces between the waveguide 304 and the silicide layer 306, and between the waveguide 304 and the silicide layer 308 are formed or oriented at least substantially perpendicular to the surface 303 of the substrate 302. In various embodiments, the waveguide 304 may have a width of between about 10 nm and about 100 nm, e.g. between about 10 nm and about 80 nm, between about 10 nm and about 50 nm, between about 10 nm and about 30 nm, between about 30 nm and about 100 nm or between about 50 nm and about 100 nm.

In various embodiments, each of the silicide layers 306, 308, may be used as an absorbing layer or material, for example for detecting surface plasmon polariton (SPP) signal.

In various embodiments, each of the silicide layers 306, 308 may have or may be of a material having a complex refractive index, where the complex refractive index may have a real index of between about 1 and about 6 (e.g. between about 1 and about 4, between about 1 and about 2 or between about 3 and about 6) and an imaginary index of between about 0 and about 5.5 (e.g. between about 0 and about 4, between about 0 and about 2, or between about 3 and about 5.5).

In various embodiments, the silicide layer 306 may have the same material as that of the silicide layer 308 or both silicide layers 306, 308 may have different materials, i.e. different silicide materials. The material of each of the silicide layers 306, 308 may include but not limited to cobalt silicide (CoSi), nickel silicide (NiSi), titanium silicide (TiSi), palladium silicide (PdSi), hafnium silicide (HfSi), niobium silicide (NbSi), platinum silicide (PtSi), vanadium silicide (VSi), tantalum silicide (TaSi) or any combinations thereof.

In various embodiments, each of the silicide layers 306, 308 may extend through the absorber region 310 and the contact region 312 of the plasmonic detector portion 313. In various embodiments, each of the silicide layers 306, 308 may not extend to the plasmonic waveguide portion 314.

In various embodiments, each of the silicide layers 306, 308 may have a width of between about 1 nm and about 10 nm, e.g. between about 1 nm and about 5 nm, between about 1 nm and about 3 nm or between about 5 nm and about 10 nm.

In various embodiments, any one of the silicide layers 306, 308 may be a metal layer (e.g. a first metal layer).

The photodetector 300 may further include a metal layer (e.g. a second metal layer) 316 formed adjacent to the silicide layer 306. The photodetector 300 may further include a metal layer (e.g. a third metal layer) 318 formed adjacent to the silicide layer 308.

Each of the metal layers 316, 318 are formed on the surface 303 of the substrate 302. Each of the metal layers 316, 318 may extend through the absorber region 310, the contact region 312 and the plasmonic waveguide portion 314. Each of the metal layers 316, 318 may be in direct contact with the silicide layers 306, 308 respectively, for example in the contact region 312.

In various embodiments, the metal layer 316 may have the same material as that of the metal layer 318 or both metal layers 316, 318 may have different materials. The material of each of the metal layers 316, 318 may include but not limited to copper (Cu), aluminium (Al), gold (Au), silver (Ag) and alloys of these materials.

The photodetector 300 may further include a dielectric layer (e.g. a first dielectric layer) 320 formed between the silicide layer 306 and the metal layer 316. The dielectric layer 320 may be formed at least partially or extending partially in a longitudinal direction (z-direction as illustrated in FIG. 3A) of the waveguide 304. The photodetector 300 may further include a dielectric layer (e.g. a second dielectric layer) 322 formed between the silicide layer 308 and the metal layer 318. The dielectric layer 322 may be formed at least partially or extending partially in a longitudinal direction (z-direction as illustrated in FIG. 3A) of the waveguide 304. In various embodiments, each of the dielectric layers 320, 322 may extend through the plasmonic waveguide portion 314 and the absorber region 310. In various embodiments, each of the dielectric layers 320, 322 may not extend to the contact region 312. In various embodiments, each of the dielectric layers 320, 322 may have a width of between about 1 nm and about 40 nm, e.g. between about 1 nm and about 20 nm, between about 1 nm and about 10 nm or between about 10 nm and about 40 nm.

In various embodiments, the dielectric layer 320 may have the same material as that of the dielectric layer 322 or both dielectric layers 320, 322 may have different materials.

The material of each of the dielectric layers 320, 322 may include but not limited to silicon oxide (SiOₓ), silicon nitride (SiN), silicon oxynitride (SiON), hafnium oxide (HfO₂), hafnium oxynitride (HfON) or any other high-κ dielectric materials.

In various embodiments, the respective permittivities of the dielectric layers 320, 322 may be lower than the respective permittivities of the silicide layers 306, 308. In various embodiments, the respective permittivities of the silicide layers 306, 308 may be lower than a permittivity of the waveguide 304.

As shown in FIG. 3A, a voltage, as represented by 330 may be applied to the contact region 312, between the metal layer 316 and the metal layer 318. Therefore, a voltage may be applied between the silicide layer 306 and the silicide layer 308.

In various embodiments, respective Schottky barriers (or silicide diodes) may be formed at the respective interfaces between the waveguide 304 and the silicide layer 306, and between the waveguide 304 and the silicide layer 308. In various embodiments, the respective Schottky barriers may be oppositely biased, e.g. one Schottky barrier is forward biased while the other is reversed biased, e.g. when the voltage 330 is applied.

In various embodiments, the photodetector 300 may detect the SPP signal propagating along the metal 316/dielectric 320/Si 304/dielectric 322/metal 318 structure in the plasmonic waveguide portion 314, based on the two silicide layers 320, 322, placed on opposite sidewalls of the Si waveguide 304 in the absorber region 310 of the plasmonic detector portion 313.

While not shown, a cladding layer (e.g. SiO₂) may be provided over the photodetector 300 to encapsulate the photodetector 300. In other words, the photodetector 300 may be embedded in a cladding layer of for example SiO₂.

FIG. 3B shows a schematic cross-sectional view of the photodetector 300 of the embodiment of FIG. 3A along the line A1-A1′, at the plasmonic waveguide portion 314. At the plasmonic waveguide portion 314, the photodetector 300 includes a plasmonic waveguide structure or arrangement of “metal/isolator (or dielectric)/waveguide (e.g. Si)/isolator (or dielectric)/metal”.

Each of or any one of the interfaces defined between the dielectric layer 320 and the waveguide 304, between the dielectric layer 322 and the waveguide 304, between the metal layer 316 and the dielectric layer 320, and between the metal layer 318 and the dielectric layer 322, may be at least substantially perpendicular to the surface 303 of the substrate 302.

The waveguide 304, the metal layers 316, 318 and the dielectric layers 320, 322 may have at least substantially similar heights, h1. In various embodiments, h1 may depend on the height of the waveguide (e.g. Si) 304, which may be between about 100 nm and about 500 nm, e.g. between about 100 nm and about 300 nm, between about 100 nm and about 200 nm, or between about 300 nm and about 500 nm.

FIG. 3C shows a schematic cross-sectional view of the photodetector 300 of the embodiment of FIG. 3A along the line A2-A2′, at the absorber region 310. At the absorber region 310, the photodetector 300 has a plasmonic detector structure or arrangement of “metal/isolator (or dielectric)/silicide/waveguide (e.g. Si)/silicide/isolator (or dielectric)/metal”.

Each of or any one of the interfaces defined between the silicide layer 306 and the dielectric layer 320, between the silicide layer 308 and the dielectric layer 322, between the metal layer 316 and the dielectric layer 320, and between the metal layer 318 and the dielectric layer 322, may be at least substantially perpendicular to the surface 303 of the substrate 302.

The waveguide 304, the silicide layers 306, 308, the metal layers 316, 318 and the dielectric layers 320, 322 may have at least substantially similar heights, h2. The height, h2, may be at least substantially same as h1.

FIG. 3D shows a schematic cross-sectional view of the photodetector 300 of the embodiment of FIG. 3A along the line A3-A3′, at the contact region 312. At the contact region 312, the photodetector 300 has a structure or arrangement of “metal/silicide/waveguide (e.g. Si)/silicide/metal”.

Each of or any one of the interfaces defined between the silicide layer 306 and the metal layer 316, and between the silicide layer 308 and the metal layer 318 may be at least substantially perpendicular to the surface 303 of the substrate 302.

The waveguide 304, the silicide layers 306, 308, and the metal layers 316, 318 may have at least substantially similar heights, h3. The height, h3, may be at least substantially same as h1 and h2.

The absorber region 310 may have a length or absorption length, L_{abs}, of between about 0.5 μm and about 10 μm, e.g. between about 0.5 μm and about 5 μm, between about 0.5 μm and about 2 μm, between about 2 μm and about 10 μm, or between about 5 μm and about 10 μm. The contact region 312 may have a length, of of between about 0.2 μm and about 20 μm, e.g. between about 0.2 μm and about 10 μm, between about 0.2 μm and about 5 μm, between about 1 μm and about 20 μm, between about 1 μm and about 5 μm, between about 5 μm and about 20 μm or between about 10 μm and about 20 μm.

As illustrated in FIGS. 3A to 3D, the photodetector 300 may be a silicon (Si) waveguide-based silicide Schottky barrier detector (SBD) having a horizontal structure or arrangement, i.e. the waveguide 304, the silicide layers 306, 308, the metal layers 316, 318 and the dielectric layers 320, 322 may be arranged one after the other in the x-direction illustrated.

In one embodiment, the metal layers 316, 318, may be copper (Cu), and the dielectric layers 320, 322 may be silicon oxide (SiO₂). Therefore, the photodetector 300 may have a horizontal plasmonic waveguide structure of Cu/SiO₂/Si/SiO₂/Cu in the plasmonic waveguide portion 314. At the absorber region 310, respective thin silicide layers 306, 308 may be inserted or formed between the Si core waveguide 304 and the respective dielectric layers 320, 322 on opposite sides of the Si core waveguide 304 to form a horizontal structure of Cu/SiO₂/silicide/Si/silicide/SiO₂/Cu. The absorber region 310 may have a length, L_{abs}, to absorb surface plasmon polariton (SPP) signals propagating along the plasmonic waveguide of Cu/SiO₂/Si/SiO₂/Cu.

At the contact region 312, at the rear of the photodetector 300, a horizontal structure of Cu/silicide/Si/silicide/Cu is provided to form the electrode terminals.

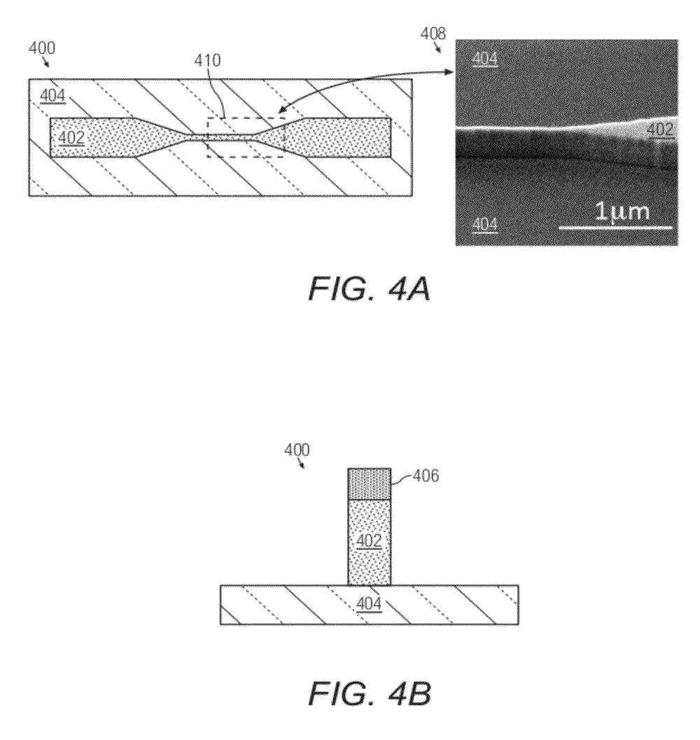

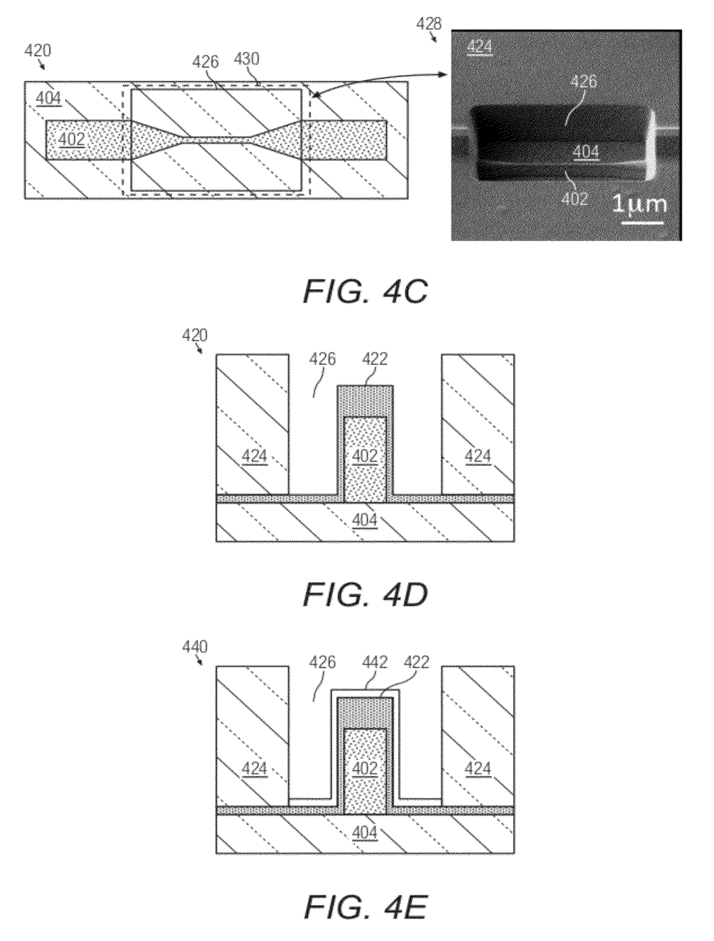

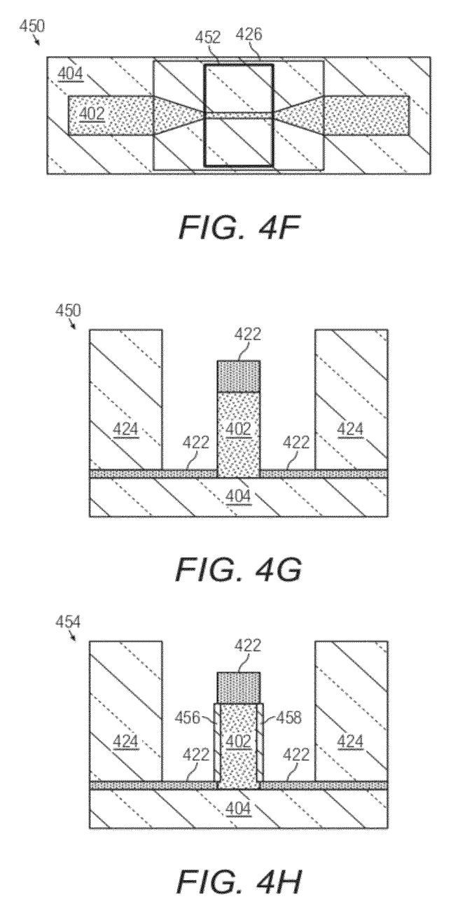

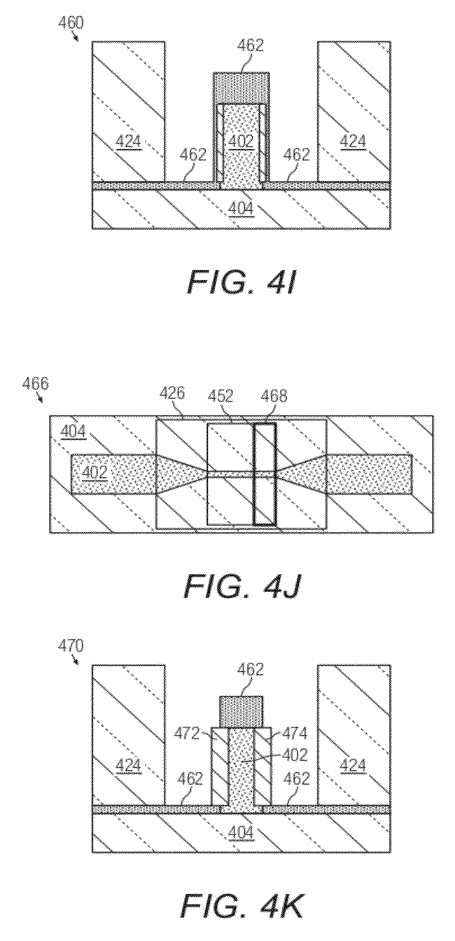

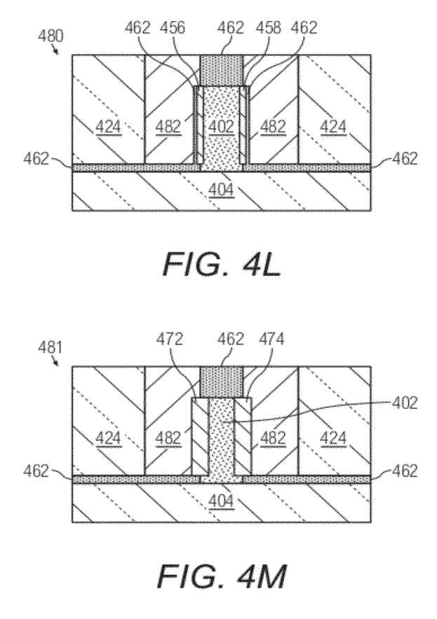

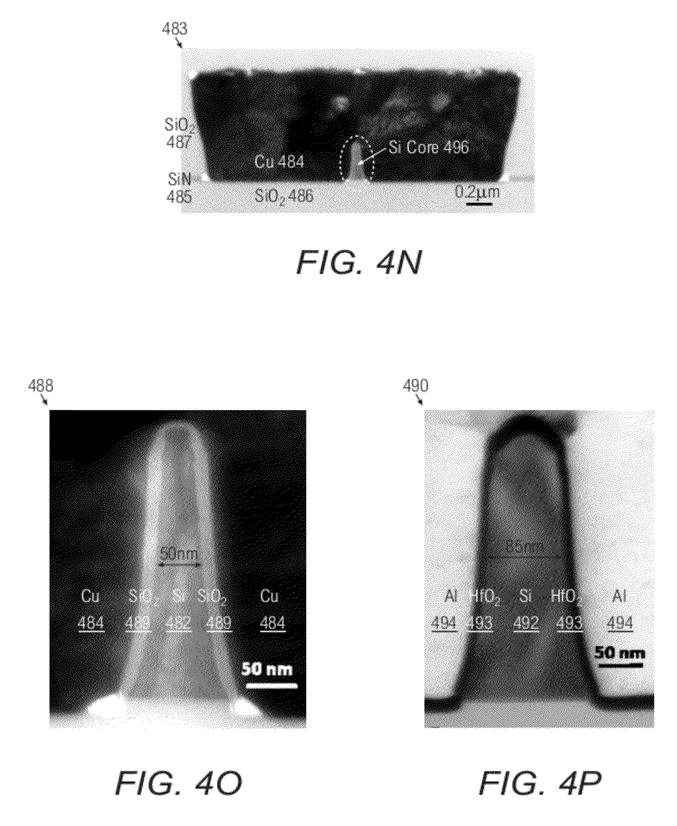

FIGS. 4A to 4M show the top or cross-sectional views of a fabrication process to manufacture a photodetector, according to various embodiments. The fabrication parameters may be determined during the processing.

The fabrication process begins with a silicon-on-insulator (SOI) wafer. The SOI wafer includes a layer of silicon (Si) on an insulator (SiO₂) layer. A silicon oxide (SiO₂)/silicon nitride (SiN)/silicon oxide (SiO₂) hard mask is then deposited on the SOI wafer. The silicon oxide (SiO₂)/silicon nitride (SiN)/silicon oxide (SiO₂) hard mask may be deposited using a plasma-enhanced chemical vapour deposition (PECVD) process sequentially. The SiO₂ layers may result in a better waveguide profile while the SiN layer may be used as a stopping layer for a chemical mechanical polishing (CMP) process to be carried out in a later process. However, it should be appreciated that a single mask layer (e.g. SiO₂) may instead be used.

The hard mask is then patterned and the silicon layer of the SOI wafer may then be etched based on the hard mask, thereby transferring the pattern of the hard mask onto the silicon layer for patterning a waveguide. In the etching process, the SiO₂/SiN/SiO₂ hard mask is first dry etched using a photoresist as a mask. The photoresist is then stripped or removed. The silicon layer of the SOI wafer may then be dry etched down to the SiO₂ insulator layer of the SOI wafer based on the etched SiO₂/SiN/SiO₂ hard mask to form a waveguide. This etching process may provide a good profile of the waveguide. During the etching process, the upper SiO₂ layer of the hard mask may be removed and after the etching process, the SiN layer and the lower SiO₂ layer of the hard mask may be maintained over the silicon waveguide. The SiN layer may be used as a stopping layer for a chemical mechanical polishing (CMP) process to be carried out in a later process.

FIGS. 4A and 4B show the top and cross-sectional views respectively of the structure 400 that may be obtained. The structure 400 includes a silicon layer 402, which has been patterned to form a waveguide, on a SiO₂ layer 404. The structure further includes a SiN layer 406 over the silicon waveguide 402. While not shown in FIG. 4B, it should be appreciated that the lower SiO₂ layer of the hard mask is present between the silicon layer 402 and the SiN layer 406. For illustration and clarity purposes, the SiN hard mask layer 406 is not shown in the schematic top view of the structure 400 of FIG. 4A. FIG. 4A further shows a scanning electron image (SEM) image 408 of a portion, as highlighted by the dotted box 410, of the structure 400.

Subsequently, deposition of silicon nitride (SiN) may be carried out over the structure 400, followed by deposition of silicon oxide (SiO₂) over the structure 400. The silicon nitride (SiN) and the silicon oxide (SiO₂) may be deposited using a plasma-enhanced chemical vapour deposition (PECVD) process sequentially. A window is then opened on the deposited SiO₂, by depositing and patterning a photoresist over the deposited SiO₂, and dry etching the deposited SiO₂ using the photoresist as the mask, and using the deposited SiN as an etch stop layer.

FIGS. 4C and 4D show the top and cross-sectional views respectively of the structure 420 that may be obtained. The structure 402 includes a layer of deposited SiN 422, which includes the SiN hard mask 406 over the top of the silicon waveguide 402. The SiN layer 422 is deposited on the sidewalls of the silicon waveguide 402 and also on the surface of the SiO₂ layer 404 of the SOI wafer. The structure 420 further includes the SiO₂ layer 424 deposited over the SiN layer 422, with a window, as represented by the box 426, that is opened on the SiO₂ layer 424 to provide access to the silicon waveguide 402. For illustration and clarity purposes, the SiN layer 422 and the SiO₂ layer 424 are not shown in the schematic top view of the structure 420 of FIG. 4C. FIG. 4C further shows a scanning electron image (SEM) image 428 of a portion, as highlighted by the dotted box 430, of the structure 420.

Subsequently, a thin layer of SiO₂ is deposited within the window 426. FIG. 4E shows the cross-sectional view of the structure 440 that may be obtained. The structure 440 includes a layer of SiO₂ 442 deposited within the window 426, over the layer of SiN 422.

Silicide window opening is then performed, by depositing and patterning a photoresist over the silicon waveguide 402, followed by dry etching of the SiO₂ layer 442, stripping or removal of the photoresist, and wet etching of the SiN layer 422.

FIGS. 4F and 4G show respectively the top view of the structure 450 and the cross-sectional view of the structure 450 that may be obtained within the silicide window, as represented by the box 452, that is opened, where the SiO₂ layer 442 has been etched away. A part of the SiN 422 over the silicon waveguide 402 remains as the SiN 422 on the sidewall of the silicon waveguide 402 is thinner than the SiN 422 over the top of the silicon waveguide 402. For illustration and clarity purposes, the SiN layer 422 and the SiO₂ layer 424 are not shown in FIG. 4F.

A metal (e.g. tantalum (Ta), nickel (Ni), etc) may then be deposited on the sidewalls of the silicon waveguide 402 within the silicide window 452, followed by silicidation by a rapid thermal annealing (RTA) process to form thin silicide on the sidewalls of the silicon waveguide 402, and then selective wet etching of the un-reacted metal. The self-aligned silicide (SALICIDE) process may be used for forming the silicides on the sidewalls of the silicon waveguide 402.

FIG. 4H shows the cross-sectional view of the structure 454 that may be obtained, including silicide layers 456, 458, formed on the sidewalls of the silicon waveguide 402 within the silicide window 452.

A thin layer of SiN may then be deposited to surround the silicon waveguide 402 within the silicide window 452, thereby encapsulating the silicide layers 456, 458. FIG. 4I shows the cross-sectional view of the structure 460 that may be obtained. The SiN layer 462 includes the SiN layer 422 and the thin layer of SiN deposited that encapsulates the silicide layers 456, 458 over the sidewalls of the silicon waveguide 402.

Contact region window opening is then performed, by depositing and patterning a photoresist over the SiN layer 462, and dry etching of the SiN layer 462 using the photoresist as the mask. FIG. 4J shows the top view of the structure 466 that may be obtained, showing the contact region window, as represented by the box 468, that is opened. For illustration and clarity purposes, the SiO₂ layer 424, the silicide layers 456, 458 and the SiN layer 462 are not shown in FIG. 4F. Similar to the process of silicide window opening, after the contact region window opening process, a part of the SiN 462 over the silicon waveguide 402 remains as the SiN 462 over the sidewalls of the silicon waveguide 402 is thinner than the SiN 462 over the top of the silicon waveguide 402.

A metal (e.g. tantalum (Ta), nickel (Ni), etc) may then be deposited on the sidewalls of the silicon waveguide 402 within the contact region window 468, followed by silicidation by a rapid thermal annealing (RTA) process to form thick silicides on the sidewalls of the silicon waveguide 402, and then selective wet etching of the un-reacted metal. The self-aligned silicide (SALICIDE) process may be used for forming the silicides on the sidewalls of the silicon waveguide 402.

FIG. 4K shows the cross-sectional view of the structure 470 that may be obtained, including silicide layers 472, 474, formed on the sidewalls of the silicon waveguide 402 within the contact region window 468. The thick silicide layers 472, 474, may prevent diffusion of metal (e.g. Cu) that is to be deposited in a later process between the silicide layers 472, 474 and the SiO₂ layer 424.

Subsequently, a metal (e.g. copper (Cu)) may be deposited over the entire structure that has been processed as described above, followed by a planarization process, for example a chemical mechanical planarization or polishing (CMP) to remove a portion of the deposited metal, and stopping on the SiN 462. The SiN 462 over the top of the silicon waveguide 402 is maintained to minimise or avoid electrical short.

FIG. 4L shows the cross-sectional view of the structure 480 that may be obtained, at the portion within the silicide window 452, to form an absorber region (e.g. 310 of FIG. 3A). The structure 480 includes the deposited metal (e.g. Cu) 482.

FIG. 4M shows the cross-sectional view of the structure 481 that may be obtained, at the portion within the contact region window 468, to form a contact region (e.g. 312 of FIG. 3A). The structure 481 includes the deposited metal (e.g. Cu) 482.

Subsequently, one or more metal (e.g. aluminium (Al)) electrodes or contacts may be formed, for example at the contact region (e.g. 312 of FIG. 3A).

FIG. 4N shows a cross sectional electron transmission microscopy (XTEM) image 483 of a front view of a photodetector, according to various embodiments, at a nanoplasmonic waveguide portion of the photodetector. The photodetector includes a nanoplasmonic waveguide including a Si core 496 (e.g. equivalent to 402) and a layer of Cu 484 (e.g. equivalent to 482) surrounding the Si core 496. The nanosplamonic waveguide is formed on a layer of SiN 485 (e.g. equivalent to 462) over a SiO₂ layer 486 (e.g. equivalent to 404), and is surrounded by a SiO₂ layer 487 (e.g. equivalent to 424).

FIG. 4O shows a cross sectional transmission electron microscopy (XTEM) image 488 of a front view of the nanoplasmonic waveguide of the embodiment of FIG. 4N, at the portion within the dotted ellipse illustrated in FIG. 4N. The XTEM image 488 shows a nanoplasmonic waveguide including a Si core 496 surrounded by a dielectric layer of SiO₂ 489 and a metal layer of Cu 484. The Si core 496 may have a width of about 50 nm at the central portion.

FIG. 4P shows a cross sectional transmission electron microscopt (XTEM) image 490 of a front view of a nanoplasmonic waveguide of a photodetector, according to various embodiments, at a nanoplasmonic waveguide portion of the photodetector. The XTEM image 490 shows a nanoplasmonic waveguide including a Si core 492 surrounded by a dielectric layer of HfO₂ 493 and a metal layer of Al 494. The Si core 496 may have a width of about 85 nm at the central portion.

Various embodiments may provide one or more of the following advantages: (i) As the silicide layers may be fabricated using the self-aligned silicide (SALICIDE) process, and that the thicknesses of the silicide layers may be precisely or more accurately controlled, e.g. by the temperature for solid-phase reaction, the fabrication of the photodetector of various embodiments is easy and straightforward, and is fully Si-CMOS compatible; (ii) The metal-semiconductor waveguide-metal structure with a semiconductor layer that is sufficicently thin to be fully depleted enables a broader tuning range of the Schottky barrier height, Φ_{B} by an applied voltage through the Schottky effect; (iii) By selecting a silicide with suitable optical parameters, the SPP model may be concentrated in the thin silicide layers to be quickly absorbed, even if the silicide layers are very thin (e.g. approximately 2 nm) and short (e.g. approximately 1 μm). The small areas of the silicide layers may result in only a small or reduced dark current, and/or may tolerate a low Schottky barrier height, Φ_{B}, to improve the responsivity of the photodetector; (iv) The photodetector of various embodiments may offer very high speed due to its ultra-compact structure, and (v) The photodetector of various embodiments may offer high responsivity.

A 2-dimensional (2-D) optical simulation method for the photodetector of various embodiments will now be described. The simulation may be carried out using the software FullWAVE from RSOFT. The FullWAVE software is based on a finite-difference time-domain (FDTD) method.

For the optical simulation method, a very fine and non-uniform grid (e.g. about 0.5 nm at the bulk and about 0.1 nm near the interface) is set, to capture the field change around the very thin silicide layers (e.g. 306, 308). As a 3-D FDTD simulation with such a fine grid size needs a very long computational time, the 2-D FDTD simulation used may offer simplification, which corresponds to an infinite height of the photodetector (e.g. 300, FIGS. 3A to 3D), for example in the direction of the y-axis as shown in FIGS. 3A to 3D.

While the height dependence of plasmonic slot waveguides may become weak with increasing height, for example for a height of 0.3 μm and above, the 2-D simplification may not cause any significant error for the photodetector of various embodiments having a height of approximately 0.34 μm (e.g. h1, h2, h3).

A fundamental 1550 nm (1.55 μm) transverse electric (TE) mode light (the electric field is parallel to the x-axis) may be launched at the plasmonic slot waveguide to propagate through the photodetector. A perfectly matched layer may be used to attenuate the field within its region without back reflection. The perfectly matched layer is a boundary condition used in simulation, which means that light is substantially or totally absorbed without reflection at this layer.

Copper (Cu) is used as the metal as it a metal used in CMOS technology and that Cu-waveguide has a much lower propagation loss than the Al-counterpart. The complex refractive index of Cu at about 1.55 μm is about 0.606+8.92i. The isolator or dielectric may be silicon oxide (SiO₂) or silicon nitride (Si₃N₄), with the refractive indices of about 1.44 and 2.0, respectively. The refractive index for silicon (Si) is about 3.45.

Different silicides have different complex refractive indices (n+ki, where n is the real component and k is the imaginary component). The n and k values for various silicides at about 1550 nm are listed in Table 1 below, which are mostly measured on the Si (100) surface, while the silicide layers in the photodetector of various embodiments are on the Si (110) surfaces (i.e. on the sidewalls of the Si waveguide). Both the electrical and optical properties of silicides may depend on the orientation. However, the possible orientation dependence is ignored in the simulation due to a lack of optical and electrical information on the Si (110) surface.

A part of Si may be consumed or used to form silicide through solid phase reaction of as-deposited metal on Si, with Si. The amount of consumed Si may depend on the silicide itself. For the simulation, a (W_{silicide}/2)-thick Si is assumed to be consumed on one side of the Si waveguide to form a W_{silicide}-thick silicide for all silicides, i.e., the Si core width (W_{Si}) in the plasmonic waveguide portion (e.g. 314, FIG. 3A) becomes (W_{Si}−W_{silicide}) in the plasmonic detector portion (e.g. 313, FIG. 3A).

The absorption or power absorption of the photodectector of various embodiments will now be described, using the structure Cu/isolator/silicide/Si/silicide/isolator/Cu as a non-limiting example. Based on the embodiments of FIGS. 3A to 3D, the absorber region 310 has a Cu/isolator/silicide/Si/silicide/isolator/Cu structure, which may be regarded as a plasmonic waveguide.

In order to calculate the propagation loss, the parameters of the plasmonic waveguide may be set as follows: the width, W_{silicide}, of each silicide layer is about 5 nm (which is formed from part of the Si core and the metal deposited on each side of the Si core), the width, W_{Si}, of the Si core is about 50 nm (thus, the actual Si core width is about 45 nm as about 2.5 nm of the Si core may be consumed on each side to form a part of a respective silicide layer) and the isolator is SiO₂ with a width, W_{SiO2}, of about 10 nm. The n and k values of the silicide may vary from 1 to 6 and 0 to 5.5, respectively, which include most silicides.

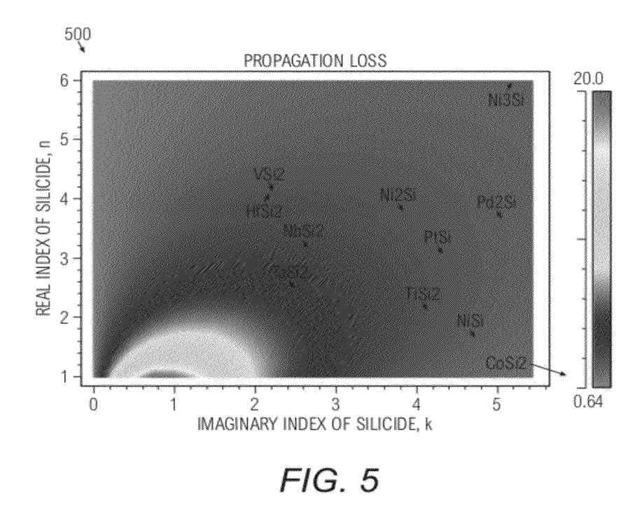

FIG. 5 shows a map 500 of calculated propagation loss (in dB/μm) as a function of the real and imaginary index of the silicide, for a Cu/SiO₂ (10 nm)/silicide (5 nm)/Si (45 nm)/silicide (5 nm)/SiO₂ (10 nm)/Cu plasmonic waveguide. The positions corresponding to different silicides, as listed in Table 1 below, are indicated in the map 500. As illustrated in FIG. 5, the propagation loss of the waveguide with silicide depends on not only the imaginary index of silicide, but also the real index of silicide. While not wishing to be bound by any theory, this behavior may be explained by the continuity of electric displacement normal to the interfaces, e.g. the interface between the Si core and the silicide. For comparison, the corresponding plasmonic waveguide without silicide layers has a propagation loss of approximately 0.85 dB/μm.

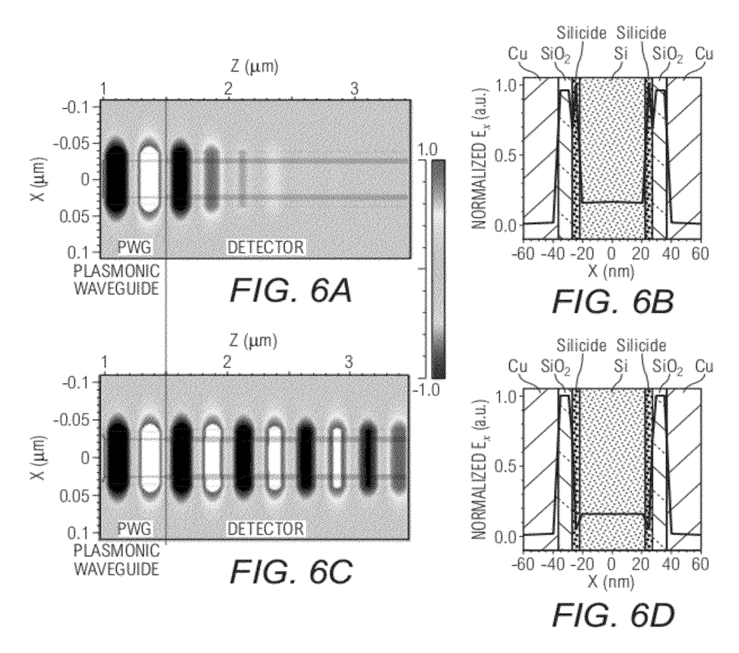

FIGS. 6A and 6B show respectively the y-component magnetic field (H_{y}) distributions along the waveguide (z-direction) and the x-component electric field (Eₓ) along a cross section of the waveguide for a silicide having a complex index of 1.0+1.5i.

FIGS. 6C and 6D show respectively the y-component magnetic field (H_{y}) distributions along the waveguide (z-direction) and the x-component electric field (Eₓ) along a cross section of the waveguide for a silicide having a complex index of 4.0+5.0i.

Due to the continuity of electric displacement normal to the interfaces, the boundary conditions are: ε_{Si}Eₓ(Si⁻)=|ε_{silicide}|Eₓ(silicide⁺) and |ε_{silicide}|Eₓ(silicide⁻)=ε_{SiO2}Eₓ(SiO₂⁻), where ε_{silicide} (=ε′+ε″i=(n+ki)²=(n²−k²)+(2nk)i) is the silicide permittivity and |ε_{silicide}|(=\sqrt{ε′²+ε″²}) is its absolute value, ε_{Si} (=11.9) and ε_{SiO2} (=2.0) are the permittivity of Si and SiO₂, respectively.

In the embodiment where the silicide index is 1.0+1.5i, |ε_{silicide}|=3.5 is smaller than ε_{Si}, thus the electric field is confined in the silicide and the SiO₂ regions, as shown in FIG. 6B, thus leading to a quick attenuation of the propagating SPP mode, as shown in FIG. 6A.

In the embodiment where the silicide index is 4.0+5.0i, the electric field in the silicide layer is smaller than that in the Si layer due to a large |ε_{silicide}| of 41, as shown in FIG. 6D. The silicide behaves as a metal for the plasmonic device or photodetector and the waveguide has a relatively low propagation loss, as shown in FIG. 6C.

In contrast to a conventional waveguide where the propagation loss should be small, the propagation loss of the waveguide with silicide or silicide layer(s) of the photodetector of various embodiments should be large for light absorption. Therefore, among the silicides listed in Table 1 below, TaSi₂ may be used for the photodetector of various embodiments as it has the lowest |ε_{silicide}|, where TaSi₂ is also a silicide used in the standard CMOS technology. Moreover, based on the above analysis, it is expected that the permittivity (hence, the refractive index) of the isolator should be high.

A map of propagation loss as a function of the real and imaginary index of the silicide, for a Cu/SiN/silicide/Si/silicide/SiN/Cu plasmonic waveguide has also been generated (result not shown), which is similar to map 500 of FIG. 5, but with a larger propagation loss. For example, the maximum propagation loss increases from about 20 dB/μm to about 35 dB/μm, and the propagation loss of TaSi₂-waveguide increases from about 4.07 dB/μm to about 7.87 dB/μm by replacing SiO₂ with Si₃N₄ as the dielectric or isolator. Therefore, in various embodiments of the photodetector, Si₃N₄ may be chosen as the isolator and TaSi₂ may be chosen as the silicide.

A silicide with a smaller permittivity may provide a larger propagation loss. The optical property of silicide may be majorly determined by the silicide itself. It is expected that alloying of two or three silicides, i.e. ternary or quaternary silicides formed by co-deposited metals with Si, may have different optical properties as compared to individual silicides. For example, Co₁₋ₓNiₓSi₂ has electrical properties (e.g. Schottky barrier height and resistivity) between that of CoSi₂ and NiSi. It may be possible to obtain a silicide with a low |ε_{silicide}|, owing to the huge number of ternary or quaternary silicides with different component ratios that may be possible. Based on the map 500 of FIG. 5, an ideal silicide may be defined for a silicide that is located at around the maximum propagation loss region, e.g. a silicide having a complex index of about 1+1.5i.

The propagation loss of a plasmonic waveguide with silicide may be caused by light absorption in the Cu, isolator, silicide, and Si regions, where the absorption in the silicide region contributes to a photocurrent. For a L_{abs}-long waveguide, the effective absorption (A) may be expressed as:

A=γ_{c}·(1-10^{-α·L}^{_{abs}})·ration (Equation 1),

where γ_{c} is the coupling efficiency from the plasmonic waveguide portion (e.g. 314) to the plasmonic detector portion (e.g. 313), α is the propagation loss in unit dB/μm, L_{abs} (e.g. 310, FIG. 3A) is the waveguide length in unit μm, and ratio is the power absorbed in silicide over the total power absorbed.

Table 1 shows the calculated optical properties for a 1-μm-long Cu/SiN (10 nm)/silicide (5 nm)/Si(45 nm)/silicide (5 nm)/SiN (10 nm)/Cu waveguide at a wavelength of about 1550 nm for different silicides.

TABLE 1

| | | | Calculated optical properties | | | | | |
|---|---|---|---|---|---|---|---|---|
| | Index | | α | | | | Φₙ | ρ |
| | n | k | (dB/μm) | ratio | γ_{C} | A | (eV) | (μΩ · cm) |
| CoSi₂ | 0.91 | 6.62 | 2.05 | 0.25 | 0.99 | 0.095 | 0.67 | 9-20 |
| Ni₃Si | 5.90 | 5.15 | 2.81 | 0.45 | 1.00 | 0.212 | N.A. | 70-106 |
| Ni₂Si | 3.76 | 3.87 | 4.27 | 0.54 | 0.99 | 0.331 | 0.66 | 30-60 |
| NiSi | 1.54 | 4.73 | 3.61 | 0.48 | 0.99 | 0.263 | 0.66 | 14-20 |
| TiSi₂ | 2.06 | 4.13 | 4.74 | 0.57 | 0.99 | 0.369 | 0.60 | 11-15 |
| Pd₂Si | 3.75 | 5.14 | 3.44 | 0.48 | 0.99 | 0.258 | 0.74 | 13-18 |
| HfSi₂ | 4.05 | 2.04 | 4.43 | 0.56 | 0.99 | 0.354 | 0.60 | >60 |
| NbSi₂ | 3.18 | 2.61 | 6.02 | 0.64 | 0.99 | 0.472 | 0.62 | 22-50 |
| PtSi | 3.09 | 4.25 | 4.35 | 0.54 | 0.99 | 0.337 | 0.88 | 25-35 |
| VSi₂ | 4.14 | 2.15 | 4.32 | 0.55 | 0.99 | 0.343 | 0.54 | 34-59 |
| TaSi₂ | 2.47 | 2.55 | 7.87 | 0.71 | 0.99 | 0.590 | 0.60 | 20-50 |
| Ideal | 1.00 | 1.50 | 27.51 | 0.90 | 0.98 | 0.887 | N.A. | N.A. |

where: n = real component of the complex refractive index,
k = imaginary component of the complex refractive index,
α = propagation loss,
ratio = power absorbed in silicide over the total power absorbed,
γ_{C} = coupling efficiency from the plasmonic waveguide portion to the plasmonic detector portion,
A = effective absorption,
Φₙ = electron Schottky barrier height. The corresponding hole Schottky barrier height (Φₚ) may be approximately calculated as: Φₚ ≈ E_{g} − Φₙ, where E_{g} (≈1.12 eV) is the Si band gap, and
ρ = resistivity of silicide.

The complex permittivity is related to n and k, where ε=ε′+ε″i=(n+ki)², where ε′ is the real part and ε″ is the imaginary part of the permittivity. As may be observed from Table 1, a smaller permittivity of silicide increases not only the propagation loss, but also the ratio of the power absorbed in the silicide layer due to power confinement. In addition, Table 1 shows that the SPP mode propagating along the metal/isolator/Si/isolator/metal plasmonic waveguide portion may effectively couple into the plasmonic detector portion. Therefore, the silicide material of the photodetector of various embodiments may be appropriately chosen as the permittivity of the silicide material may affect the performance of the photodetector.

The internal quantum efficiency and the external quantum efficiency of the plasmonic photodetector of various embodiments, based on the Scales' model [C. Scales and P. Berini, “Thin-film Schottky barrier photodetector models”, IEEE J. Quantum Electronics 46 (5), 633-643 (2010)], will now be described.

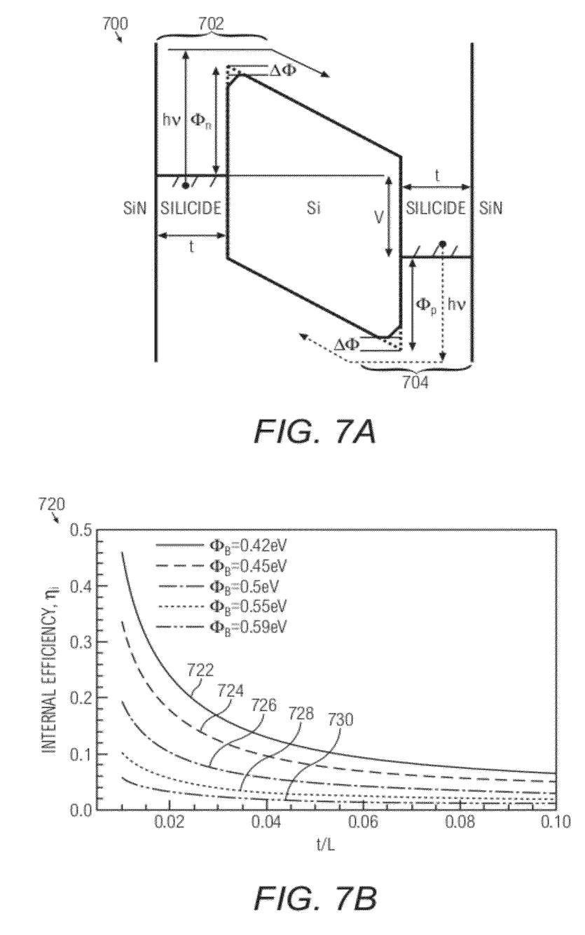

The photodetector of various embodiments has a metal-semiconductor-metal structure. FIG. 7A shows a schematic of a band diagram 700 of a silicide/Si/silicide structure under a positive bias, according to various embodiments. Under a positive bias (V), the left silicide/Si Schottky contact 702 may be reversely biased and the right silicide/Si Schottky contact 704 may be forwardly biased for electrons, and vice versa for holes. In FIG. 7A, “t” represents the silicide thickness.

In the photodetector of various embodiments, the left silicide layer of the silicide/Si Schottky contact 702 and the right silicide layer of the silicide/Si Schottky contact 704 may be assumed to absorb power equally. The hot electrons excited in the left silicide layer emits through Φₙ to be collected by the right silicide layer, and the hot holes excited in the right silicide layer emits through Φₚ to be collected by the left silicide layer. The hot electrons and holes may both contribute to the photocurrent.

In various embodiments, due to the narrow Si width, the Si layer may be fully depleted under bias and the constant electric field across the Si layer may be given by V/W_{Si} (=biasing voltage/width of silicon layer).

The applied voltage may lead to both Φₙ and Φₚ lowering. The decrease of both Φₙ and Φₚ may be predicted by the Schottky effect based on Equation 2 below:

$$Δ Φ = \sqrt{\frac{eV}{4 π {ɛ}_{0} {ɛ}_{Si} {W}_{Si}} } , \qquad ( Equation 2 )$$

where e is the electron charge, ε₀ is the permittivity of vacuum and ε_{Si} is the permittivity of silicon (Si). Based on Equation 2, for an embodiment where W_{Si} is about 45 nm and V is about 1 V, ΔΦ is approximately 0.05 eV.

For embodiments of a photodetector using TaSi₂, Φₙ is approximately 0.6 eV and Φₚ is approximately 0.5 eV. Therefore, the effective barrier heights, for Φₙ and Φₚ, under a 1 V bias may become approximately 0.55 eV and approximately 0.45 eV, respectively. Lower effective Φₙ and Φₚ may be obtained at a higher bias voltage and/or a narrower Si width. The Schottky barrier height for electron (Φₙ) is different to the Schottky barrier height for hole (Φₚ). For a particular silicide/Si diode, Φₙ+Φₚ is approximately 1.12 eV (where 1.12 eV is the energy bandgap of Si). Based on this, the TaSi₂ silicide may be assumed to have Φₙ of about 0.55 eV and Φₚ of about 0.45 eV, after taking the voltage induced barrier height lowering effect into consideration.

FIG. 7B shows a plot 720 of internal quantum efficiency (ηᵢ) of a thin-film silicide/Si Schottky-barrier photodetector of various embodiments, for different Schottky barrier heights ( _{B}), calculated based on the Scales' model [C. Scales and P. Berini, “Thin-film Schottky barrier photodetector models”, IEEE J. Quantum Electronics 46 (5), 633-643 (2010)]. The plot 720 shows the calculated ηᵢ as a function of t/L (where t is the silicide thickness and L is the hot carrier attenuation length), at hv (photon energy, where h is the Planck constant and v is frequency) of about 0.8 eV, for Φ_{B}=0.42 eV 722, Φ_{B}=0.45 eV 724, Φ_{B}=0.5 eV 726, Φ_{B}=0.55 eV 728 and Φ_{B}=0.59 eV 730. As shown in FIG. 7B, ηᵢ increases with Φ_{B} lowering (i.e. decrease in Φ_{B}) and/or silicide thickness thinning (i.e. decrease in the silicide thickness, t). Therefore, the barrier height may be tuned by an applied voltage, thus improving the internal efficiency. When t/L approaches 0 (i.e. t/L→0), the maximum ηᵢ reaches or approaches to η_{i,∞}^{t}≅(hv−Φ_{B})/hv.

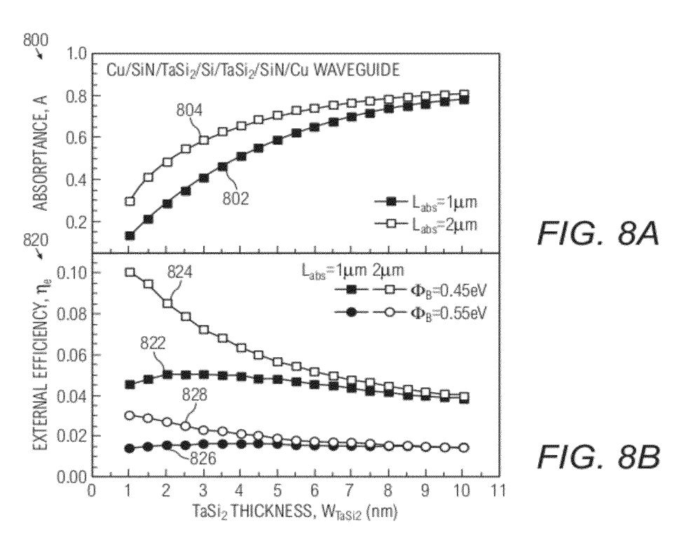

The external quantum efficiency (ηₑ) may be a function of ηᵢ, and may be given as ηₑ=A·ηᵢ, where A refers to the effective absorption (see for example Table 1), which is equivalent to the absorptance shown, for example, in FIGS. 8A, 9 and 10.

FIGS. 8A and 8B show respective plots 800, 820, of calculated absorption (or absorptance) (A) and external quantum efficiency (ηₑ) as a function of TaSi₂ thickness or width (W_{TaSi2}), according to various embodiments, for a photodetector having a structure of (Cu/SiN/TaSi₂/Si/TaSi₂/SiN/Cu). Other parameters may be set as: Si thickness or width, W_{Si}, of (50 nm−W_{TaSi2}), SiN isolator width, W_{SiN}, of about 10 nm, absorber region length, L_{abs}, of about 1 μm or about 2 μm, hot carrier attenuation length, L, assumed to be about 100 nm, Schottky height barrier, Φ_{B}, of about 0.45 eV or about 0.55 eV, and hv of about 0.8 eV.

The plot 800 shows the absorptance result 802 for L_{abs}=1 μm and the absorptance result 804 for L_{abs}=2 μm.

The plot 820 shows the ηₑ result 822 for L_{abs}=1 μm and Φ_{B}=0.45 eV, the ηₑ result 824 for L_{abs}=2 μm and Φ_{B}=0.45 eV, the ηₑ result 826 for L_{abs}=1 μm and Φ_{B}=0.55 eV and the ηₑ result 828 for L_{abs}=2 μm and Φ_{B}=0.55 eV.

As shown in FIGS. 8A and 8B, for L_{abs}=1 μm, an increase in A and a decrease in ηᵢ leads to a maximum ηₑ at W_{TaSi2} of about 2-3 nm (e.g. see results 822, 826). With an increase in L_{abs}, A increases and ηₑ is generally limited by ηᵢ, thus ηₑ monotonically increases, as W_{TaSi2} decreases (e.g. see results 824, 828).

In embodiments of a TaSi₂-photodetector, with W_{TaSi2}=2 nm, L_{abs}=2 μm and W_{Si}=50 nm, at 1 V bias (thus, Φₙ≈0.55 eV and Φₚ≈0.45 eV), the overall ηₑ (=(ηₑ(electron)+ηₑ(hole))/2) is approximately 0.056, as may be observed from FIG. 8B, which corresponds to a responsivity of approximately 0.07 A/W at about 1550 nm. In various embodiments, the responsivity may increase with an increase in the bias voltage, due to Φ_{B} lowering. However, the dark current may increase. In the photodetector of various embodiments, silicide layers may be provided on either side of a waveguide. Therefore, a pair of silicide layers may interface with respective opposite sides of the waveguide and may be regarded as two silicide diodes, with one silicide diode for electrons and the other silicide diode for holes. The overall ηₑ may be calculated as ((ηₑ(electron)+ηₑ(hole))/2). For the electron diode, the barrier height Φ_{B} may be assumed to be about 0.55 eV, and based on the ηₑ result 828 for W_{TaSi2}=2 nm and L_{abs}=2 μm, ηₑ(electron) is approximately 0.027. For the hole diode, the barrier height Φ_{B} may be assumed to be about 0.45 eV, and based on the ηₑ result 824 for W_{TaSi2}=2 nm and L_{abs}=2 μm, ηₑ(hole) is approximately 0.085. Accordingly, the overall ηₑ is approximately 0.056[(=0.027+0.085)/2].

Where an ideal silicide is adopted, the absorptance, A, is approximately 0.69 for L_{abs}=1 μm and W_{silicide}=2 nm. The overall ηₑ may be about 0.08 and the responsivity may be 0.1 A/W at a bias voltage of about 1 V, assuming the ideal silicide has at least substantially the same barrier height as TaSi₂.

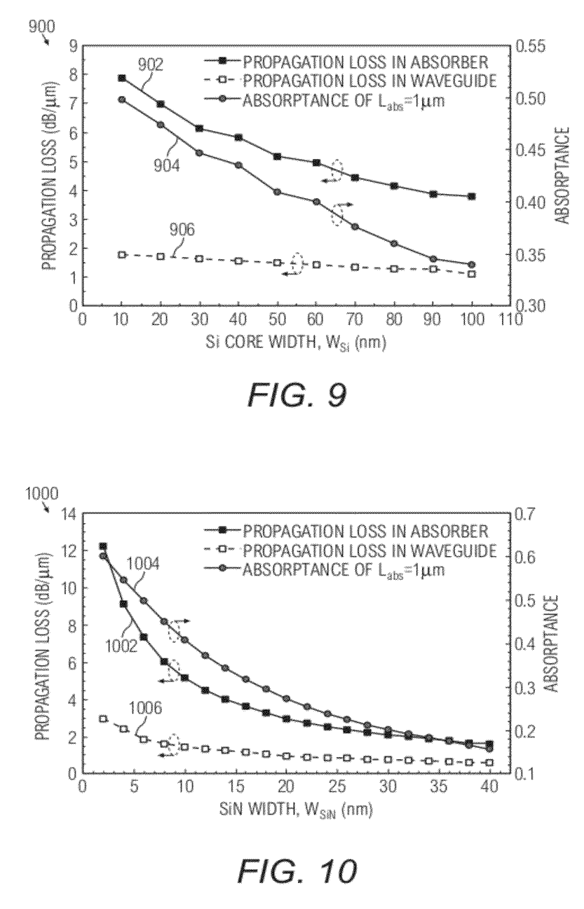

FIG. 9 shows a plot 900 of calculated propagation loss (a) and absorption (or absorptance) (A) as a function of silicon (Si) core width (W_{Si}), according to various embodiments, for a photodetector having a structure of (Cu/SiN/TaSi₂/Si/TaSi₂/SiN/Cu). The effective width of the Si core is (W_{Si}−W_{TaSi2}) Other parameters may be set as: W_{TaSi2} of about 3 nm, W_{SiN} of about 10 nm, and L_{abs} of about 1 μm.

The plot 900 shows the propagation loss result 902 and the power absorption 904 of the photodetector in the absorber region (e.g. 310). The plot 900 also shows the propagation loss result 906 for a corresponding plasmonic waveguide without silicide (i.e. Cu/SiN/Si/SiN/Cu), for comparison.

As shown in FIG. 9, both propagation loss 902 and the power absorption 904 increase, e.g. increase monotonically, as W_{Si} decreases. This shows that L_{abs} may be reduced with a decrease in W_{Si} to maintain a particular absorption. As shown in FIG. 9, the propagation loss 906 of a conventional plasmonic slot waveguide (i.e. without silicide layers) also increases with a decrease in W_{Si}.

In various embodiments, the photodetector of various embodiments may be designed or fabricated with W_{Si} of about 50 nm, as a near or substantially rectangle profile may be obtained using industry-standard lithographic process for a Si core with a width, W_{Si}, of about 50 nm and a height of about 340 nm.

FIG. 10 shows a plot 1000 of calculated propagation loss (α) and absorption (or absorptance) (A) as a function of silicon nitride (Si₃N₄) isolator width (W_{SiN}), according to various embodiments, for a photodetector having a structure of (Cu/SiN/TaSi₂/Si/TaSi₂/SiN/Cu). Other parameters may be set as: W_{TaSi2} of about 3 nm, W_{Si} of about 50 nm, and L_{abs} of about 1 μm.

The plot 1000 shows the propagation loss result 1002 and the power absorption 1004 of the photodetector in the absorber region (e.g. 310). The plot 1000 also shows the propagation loss result 1006 for a corresponding plasmonic waveguide without silicide (i.e. Cu/SiN/Si/SiN/Cu), for comparison.

As shown in FIG. 10, reducing the Si₃N₄ width W_{SiN}) may increase the propagation loss 1002 and the power absorption 1004. In addition, as shown in FIG. 10, reducing W_{SiN} also increases the propagation loss 1006 of the conventional plasmonic slot waveguide (i.e. without silicide layers). This shows that L_{abs} may be reduced with a decrease or thinning down of W_{SiN} to maintain a particular power absorption, which may lead to a smaller dark current and a higher detector speed.

The estimated dark current and speed of the photodectector of various embodiments will now be described, based on calculation.

The photodetector of various embodiments may effectively be two Schottky diodes connected or coupled to each other back-to-back, for example one Schottky diode may be forward-biased while the other may be reversed-biased, when a biasing voltage is applied to the photodetector.

The total dark current, I_{dark} is composed of both electron current and hole current, and may be expressed as

$${I}_{dark} = ( {L}_{ab s} + {L}_{con} ) \cdot height \cdot {T}^{2} ( {A}_{n}^{**} \cdot exp ( - \frac{e \cdot {Φ}_{n}}{k \cdot T} ) + {A}_{p}^{**} \cdot exp ( - \frac{e \cdot {Φ}_{p}}{k \cdot T} ) ) , \qquad ( Equation 3 )$$

where L_{abs} is the absorber region length, L_{con} is the contact region length, height refers to the waveguide height (e.g. h1 as illustrated in FIG. 3B), T is the absolute temperature, k is the Boltzmann constant, Aₙ** is the effective Richardson constant for electrons (e.g. 117 A·cm⁻²·K⁻² for electrons in Si), Aₚ** is the effective Richardson constant for holes (e.g. 32 A·cm⁻²·K⁻² for holes in Si), e is the electron charge (approximately 1.602×10⁻¹⁹ C), Φₙ is the electron Schottky barrier height, and Φₚ is the hole Schottky barrier height.

For a 2 μm long and 2 nm thick TaSi₂-detector, integrated in a 50 nm wide Si core in a metal-semiconductor-metal (MSM structure) (or equivalently a metal-dielectric-metal (MDM)) plasmonic waveguide, as described above with a responsivity of about 0.07 A/W, the dark current, I_{dark}, may be calculated to be approximately 66 nA at room temperature under a bias voltage of about 1 V. The minimum detectable power, Sₘᵢₙ (sensitivity) in dBm, which is defined as 1 dB above the optical power (in dBm) that generates a photocurrent equal to the dark current, I_{dark}, may be calculated to be approximately −29 dBm. For the ideal silicide-detector as described above with a responsivity of about 0.07 A/W, the dark current, I_{dark}, may be approximately 39 nA (due to a short L_{abs}) and Sₘᵢₙ may be approximately −33 dBm.

The speed of a photodetector may be determined by the transit time of excited carriers across the Si core and the RC delay. Assuming a drift velocity of carriers of about 1×10⁷ cm/s in Si, the transit time may be estimated to be about 0.5 ps for W_{Si}=50 nm, corresponding to a Terahertz (THz) cutoff frequency. The speed of the photodetector of various embodiments may be limited by the RC delay, which may be defined as

$${f}_{ma x} = \frac{1}{2 π \times RC} , \qquad ( Equation 4 )$$

where fₘₐₓ refers to the maximum frequency or cutoff frequency, R refers to resistance and C refers to capacitance.

Based on a simple parallel-plate model, the capacitance, C of the TaSi₂-detector as described above may be calculated to be approximately 1.75 fF. Assuming a resistivity, ρ of about 40 μQ·cm, a 2-μm-long 2-nm-thick TaSi₂ film may have a resistance, R of about 1.3 kΩ. Therefore, the cutoff frequency or speed, fₘₐₓ, of the TaSi₂-detector as described above may be estimated to be approximately 68 GHz.

For the ideal silicide-detector, assuming the same resistivity of about 40 μΩ·cm, both R and C are reduced due to a reduction in L_{abs}, and the cutoff frequency, fₘₐₓ, may be estimated to be approximately 228 GHz.

As illustrated by the above analysis, both the dark current, I_{dark}, and the speed, fₘₐₓ, may be improved by reducing the Si₃N₄ and/or Si core widths, while maintaining the responsivity of the photodetector of various embodiments.

Therefore, various embodiments of a silicide Schottky-barrier detector may be designed to detect surface plasmon polariton (SPP) signal propagating along the horizontal metal/isolator/Si/isolator/metal nanoplasmonic slot waveguide, which may be fabricated using the standard complementary metal-oxide-semiconductor (CMOS) technology. In various embodiments, silicide layers or ultrathin silicide layers may be inserted or arranged between any one or both of the isolators and Si to effectively absorb power.

In various embodiments, the Schottky barrier height may be broadly tuned through the Schottky effect, owing to the metal-Si-metal structure with a narrow or very narrow Si core waveguide.

In various embodiments, the silicide may be tantalum silicide (TaSi₂) which has the lowest permittivity among other silicides. In various embodiments, the isolator may be silicon nitride (Si₃N₄) which has a large permittivity, as compared to silicon oxide (SiO₂).

Using TaSi₂ as an example, a TaSi₂-photodetector, e.g. with optimized dimensions, may exhibit a responsivity of about 0.07 A/W, a dark current of about 66 nA at room temperature, and a speed of about 60 GHz, under a bias voltage of about 1 V. The minimum detectable power may be about −29 dBm. In contrast, for a conventional Si-waveguide based silicide Schottky barrier detector under a bias voltage of about 1 V, the conventional detector exhibits a responsivity of about 19 mA/W, a dark current of about 30 nA, and a speed of about 7 GHz.

In various embodiments, the performance of the photodetector may be further improved by reducing the width of the Si core and/or the width of the isolator. In addition, the overall performance of the photodetector may also be improved where a silicide with a smaller permittivity is adopted or employed, for example some ternary or quaternary silicides.

It should be appreciated that the photodetector of various embodiments may be integrated with other plasmonic devices to form an integrated circuit.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A photodetector comprising:
a substrate;
a waveguide formed on a surface of the substrate;
a first metal layer formed on a first side of the waveguide, wherein a first interface is defined between the waveguide and the first metal layer; and
a silicide layer formed on a second side of the waveguide, wherein a second interface is defined between the waveguide and the silicide layer, and wherein the second side is opposite to the first side; and
wherein at least one of the first interface or the second interface is at least substantially perpendicular to the surface of the substrate.

2. The photodetector as claimed in claim 1, wherein the first metal layer is another silicide layer.

3. The photodetector as claimed in claim 2, wherein the silicide layer and the other silicide layer comprise an at least substantially same material or different materials.

4. The photodetector as claimed in claim 2, wherein the silicide layer and the other silicide layer comprise a material having a complex refractive index, wherein the complex refractive index has a real index and an imaginary index, and wherein the real index is between about 1 and about 6 and the imaginary index is between about 0 and about 5.5.

5. The photodetector as claimed in claim 2, wherein the silicide layer and the other silicide layer comprise a material selected from a group consisting of cobalt silicide, nickel silicide, titanium silicide, palladium silicide, hafnium silicide, niobium silicide, platinum silicide, vanadium silicide, tantalum silicide and any combinations thereof.

6. The photodetector as claimed in claim 1, wherein a first Schottky barrier is formed at the first interface, and wherein a second Schottky barrier is formed at the second interface.

7. The photodetector as claimed in claim 6, wherein one of the first Schottky barrier or the second Schottky barrier is forward biased, and the other Schottky barrier is reverse biased when a voltage is applied between the first metal layer and the silicide layer.

8. The photodetector as claimed in claim 1, further comprising:
a second metal layer formed adjacent to the first metal layer; and
a third metal layer formed adjacent to the silicide layer.

9. The photodetector as claimed in claim 8, wherein the second metal layer and the third metal layer are formed on the surface of the substrate.

10. The photodetector as claimed in claim 8, further comprising:
a first dielectric layer formed between the first metal layer and the second metal layer; and
a second dielectric layer formed between the silicide layer and the third metal layer.

11. The photodetector as claimed in claim 10, wherein the first dielectric layer is formed partially in a longitudinal direction of the waveguide, and wherein the second dielectric layer is formed partially in the longitudinal direction of the waveguide.

12. The photodetector as claimed in claim 10, wherein the first metal layer has a first permittivity, the silicide layer has a second permittivity, the first dielectric layer has a third permittivity and the second dielectric layer has a fourth permittivity, and wherein the third permittivity and the fourth permittivity are lower than the first permittivity and the second permittivity.

13. The photodetector as claimed in claim 12, wherein the first permittivity and the second permittivity are lower than a permittivity of a material of the waveguide.

14. The photodetector as claimed in claim 10, wherein the first dielectric layer and the second dielectric layer have a width of between about 1 nm and about 40 nm.

15. The photodetector as claimed in claim 1, wherein the first metal layer and the silicide layer have a width of between about 1 nm and about 10 nm.

16. The photodetector as claimed in claim 1, wherein the waveguide comprises a semiconductor.

17. The photodetector as claimed in claim 1, wherein the waveguide comprises silicon.

18. The photodetector as claimed in claim 17, wherein the first side of the silicon waveguide and the second side of the silicon waveguide are silicon (110) crystal planes.

19. The photodetector as claimed in claim 1, wherein the waveguide has a width of between about 10 nm and about 100 nm.

20. A method of forming a photodetector, the method comprising:
providing a substrate;
forming a waveguide on a surface of the substrate;
forming a first metal layer on a first side of the waveguide, wherein a first interface is defined between the waveguide and the first metal layer; and
forming a silicide layer on a second side of the waveguide, wherein a second interface is defined between the waveguide and the silicide layer, and wherein the second side is opposite to the first side; and
wherein at least one of the first interface and the second interface is at least substantially perpendicular to the surface of the substrate.
